(19) United States
(12) Patent Application Publication
(10) Pub. No.: US 2026/0139178 A1
(43) Pub. Date: May 21, 2026

(54) COLD STORAGE MATERIAL, PREPARATION METHOD THEREFOR, AND APPLICATION THEREOF

(71) Applicant: Shenzhen International Quantum Academy, Shenzhen (CN)

(72) Inventors: Changzhao PAN, Shenzhen (CN); Shu GUO, Shenzhen (CN); Jianqiao WANG, Shenzhen (CN); Chushu FANG, Shenzhen (CN)

(73) Assignee: Shenzhen International Quantum Academy, Shenzhen (CN)

(21) Appl. No.: 19/320,277

(22) Filed: Sep. 5, 2025

(30) Foreign Application Priority Data
Nov. 21, 2024 (CN) 202411672445.4

(51) Int. Cl. C09K 5/06; C30B 9/12; C30B 29/46; F25D 3/02; F25D 16/00; F25D 23/06

(52) U.S. Cl. CPC C09K 5/06; C30B 9/12; C30B 29/46; F25D 3/02; F25D 16/00; F25D 23/065; F25D 2303/0822; F25D 2303/085

(57) ABSTRACT

A cold storage material and a preparation method therefor and an application thereof are provided. The cold storage material includes a Gd2O2Se crystal, which undergoes a phase transition near 6.22 K and exhibits high specific heat in 1-10 K temperature range with pronounced magnetocaloric effects, making it suitable as a cold storage material at liquid helium temperatures.

### CROSS-REFERENCE TO RELATED APPLICATIONS

The present application claims priority to Chinese Patent Application No. 202411672445.4, filed on Nov. 21, 2024, the content of all of which is incorporated herein by reference.

### FIELD

The present application relates to the technical field of cold storage, in particular to a cold storage material, a preparation method therefor, and an application thereof.

### BACKGROUND

Gifford-McMahon (GM) type pulse tube refrigerators, particularly high-capacity 4K GM type pulse tube refrigerators, play a critical role in creating and maintaining cryogenic environments, with extensive applications in condensed matter physics, quantum computing, cryogenic scientific instruments, superconductivity, and military industries. The efficiency of these refrigerators substantially depends on the performance of a cold storage component, and high-specific-heat materials filled inside this component are crucial to refrigeration performance. However, the specific heat capacity of existing elementary materials decreases with decreasing temperature, exhibiting significant degradation below 10 Kelvin (K), which severely affects refrigerator performance.

Magnetic cold storage materials have drawn significant attention due to their anomalous specific heat enhancement at cryogenic temperatures. Materials such as HoCu2, Er3Ni, and gadolinium oxysulfide (Gd2O2S, abbreviated as GOS) exhibit magnetic phase transitions below 10 K, demonstrating anomalous specific heat characteristics that significantly improve the Performance of the 4K refrigerators and have been widely adopted in commercial refrigeration systems. Consequently, the exploration of novel high-specific-heat cryogenic cold storage materials has become an important research direction.

Rare-earth-based compounds, particularly those containing elements such as gadolinium (Gd), dysprosium (Dy), and terbium (Tb), exhibit pronounced magnetocaloric effects due to their unpaired 4f electrons, demonstrating potential for cold storage applications. For example, GOS serves as a high-entropy-density magnetic cold storage material suitable for the temperature range of 4.2 K to 20 K, and has been widely adopted in advanced technologies, including small-scale regenerative cryogenic gas refrigerators. Although the current layered filling strategy employing HoCu2 and GOS enhances specific heat capacity in the temperature range of below 10 K, a specific heat capacity trough persists between 6-7 K, necessitating the development of novel materials to bridge this performance gap.

Potential GOS substitute materials, such as gadolinium oxyselenide and gadolinium oxytelluride, exhibit physicochemical properties similar to GOS. Due to challenges in their preparation processes, rare earth oxyselenides remain undeveloped for applications in cryogenic cold storage systems. Consequently, there is an urgent need to develop high-performance cold storage materials demonstrating pronounced magnetocaloric effects at liquid helium temperatures, which would facilitate practical applications of cold storage technologies in the liquid helium temperature range and advance the development of cryogenic refrigeration technologies.

### SUMMARY

In view of the above-mentioned deficiencies in the prior art, an object of the present application is to provide a cold storage material, a preparation method therefor, and an application thereof, aiming to solve the problem of lacking high-performance cold storage materials suitable for liquid helium temperatures with pronounced magnetocaloric effects in the prior art.

The technical solutions of the present application are as follows:

In a first aspect, the present application provides a cold storage material including a Gd2O2Se crystal.

Optionally, the Gd2O2Se crystal belongs to a trigonal crystal system, with a space group of P-3 m1.

Optionally, the Gd2O2Se crystal has unit cell parameters of a=3.88510 Å, b=3.88510 Å, c=6.88 Å, α=90°, γ=90°, γ=120⁰, and V=89.933906 Å3.

In a second aspect, the present application provides a method for preparing the cold storage material according to the first aspect, including following steps: mixing Gd2O3, Se, activated carbon powder, CsCl, and elementary iodine particles in a predetermined ratio and subjecting a mixture to grinding treatment to obtain a mixed powder; and sintering the mixed powder under vacuum conditions to obtain the cold storage material.

Optionally, a molar ratio of the Gd2O3, the Se and the activated carbon powder is 5:5:2.6 to 5:10:6; a mass ratio of the CsCl to a total mass of the Gd2O3, the Se and the activated carbon powder is 3:2 to 3:5; a mass ratio of the elemental iodine particles to the total mass of the Gd2O3, the Se and the activated carbon powder is 1:20 to 10:20.

Optionally, the sintering treatment includes: heating from an initial temperature of 20-40° C. to 950-1100° C. at a constant heating rate over 600-800 minutes, maintaining temperature for 10-48 hours, after cooling to 500-750° C. over 3-5 days, then cooling to room temperature within 10-48 hours.

In a third aspect, the present application provides an application of the cold storage material according to the first aspect in manufacture of cold storage devices or refrigeration equipment.

In a fourth aspect, the present application provides a cold storage device. The cold storage device includes a cold storage cylinder, a first partition member, a second partition member, and a third partition member arranged at intervals within the cold storage cylinder. The first partition member, the second partition member and the third partition member are configured to permit gas flow in a direction from the first partition member toward the third partition member; the first partition member, the second partition member and the cold storage cylinder form a first accommodation space; the second partition member, the third partition member and the cold storage cylinder form a second accommodation space; the first accommodation space is filled with a front-stage cold storage material and a mid-stage cold storage material; and the second accommodation space is filled with a rear-stage cold storage material.

Optionally, the front-stage cold storage material includes one or more of Er3Ni, Pb, Bi, HoCu2, and Ni; the mid-stage cold storage material includes the cold storage material; the rear-stage cold storage material includes one or more of the cold storage materials and Gd2O2S.

Optionally, the front-stage cold storage material, the mid-stage cold storage material, and the rear-stage cold storage material have progressively decreased phase transition temperatures.

Advantageous effects of the present application: a cold storage material of the present application includes a Gd2O2Se crystal, which undergoes a phase transition near 6.22 K and exhibits high specific heat within a 1-10 K temperature range, demonstrating pronounced magnetocaloric effects and being suitable for use as a cold storage material at liquid helium temperatures.

### BRIEF DESCRIPTION OF THE DRAWINGS

To more clearly illustrate the technical solutions in the embodiments of the present application, the drawings to be used in the description of the embodiments are briefly introduced below;

FIG. 1 is a schematic flow diagram of a preparation method for a cold storage material provided by the present application;

FIG. 2 is a structural schematic diagram of a cold storage device provided by the present application;

FIG. 3 is a physical photograph of the cold storage material provided by the present application;

FIG. 4 is an optical microscope observation image of the cold storage material provided by the present application;

FIG. 5 is a schematic diagram of a crystal structure of the cold storage material provided by the present application;

FIG. 6 is an X-ray diffraction pattern of a powder sample of the cold storage material provided by the present application;

FIG. 7 is a specific heat versus temperature curve for the cold storage material provided by the present application.

### REFERENCE NUMERALS

100—cold storage device; 1—cold storage cylinder; 21—first partition member; 22—second partition member; 23—third partition member; 31—front-stage cold storage material; 32—mid-stage cold storage material; 33—rear-stage cold storage material; 41—gas inlet; 42—gas outlet.

### DETAILED DESCRIPTION OF EMBODIMENTS

To make the objectives, technical solutions, and advantages of the present application clearer, the technical solutions in the embodiments of the present application are described clearly and completely below in conjunction with the accompanying drawings and embodiments. It is apparent that the described embodiments are only a part of the embodiments of the present application rather than all of them. All other embodiments obtained by those of ordinary skill in the art based on the embodiments of the present application, without creative efforts, shall fall within the protection scope of the present application. The embodiments and features of the embodiments may be combined with each other without conflict.

It should be noted that if descriptions such as “first” and “second” are involved in the implementation of the present application, these descriptions are for descriptive purposes only and should not be construed as indicating or implying relative importance or implicitly specifying the quantity of the indicated technical features. Thus, features defined with “first” or “second” may explicitly or implicitly include at least one such feature. In addition, technical solutions between various embodiments may be combined with each other, provided that such combinations can be implemented by those of ordinary skill in the art. When the combinations of technical solutions result in mutual contradiction or impossibility of implementation, such combinations shall be deemed non-existent and not within the claimed protection scope of the present application.

An embodiment of the present application provides a cold storage material including a Gd2O2Se crystal. The Gd2O2Se crystal undergoes a phase transition near 6.22 K and exhibits high specific heat within a temperature range of 1-10 K. Applications of rare earth selenides in cryogenic cold storage systems are not disclosed in the prior art. The Gd2O2Se crystal exhibits pronounced magnetocaloric effects, making it suitable for use as a cold storage material at liquid helium temperatures.

In some embodiments, the Gd2O2Se crystal belongs to a trigonal crystal system with a space group P-3 m1.

In some embodiments, the Gd2O2Se crystal has unit cell parameters of a=3.88510 Å, b=3.88510 Å, c=6.88 Å, □=90°, □=90°, γ=120°, and V=89.933906 Å3.

The embodiments of the present application further provide a method for preparing the aforementioned cold storage material, including steps of:
Mixing Gd2O3, Se, activated carbon powder, CsCl, and elemental iodine particles in a predetermined ratio and subjecting a mixture to grinding treatment to obtain a mixed powder; and
Sintering the mixed powder under vacuum conditions to obtain the cold storage material.

In some embodiments, a molar ratio of the Gd2O3, the Se and the activated carbon powder is 5:5:2.6 to 5:10:6; For example, the molar ratio of the Gd2O3, the Se, and the activated carbon powder is selected from 5:5:2.6, 5:5:5, 5:6:5, 5:8:6, or 5:10:5. A mass ratio of the CsCl to a total mass of the Gd2O3, the Se and the activated carbon powder is 3:2 to 3:5; For example, the mass ratio of CsCl to the total mass of the Gd2O3, Se, and the activated carbon powder is selected from 3:2, 3:3, 3:4, or 3:5. A mass ratio of the elemental iodine particles to the total mass of the Gd2O3, the Se and the activated carbon powder is 1:20 to 10:20. For example, the mass ratio of the elemental iodine particles to the total mass of the Gd2O3, the Se, and the activated carbon powder is selected from 1:20, 2:20, 3:20, 4:20, 6:20, 8:20, 9:20, or 10:20.

In some embodiments, the sintering treatment includes: heating from an initial temperature of 20-40° C. to 950-1100° C. at a constant heating rate over 600-800 minutes, maintaining temperature for 10-48 hours, after cooling to 500-750° C. over 3-5 days, then cooling to room temperature within 10-48 hours.

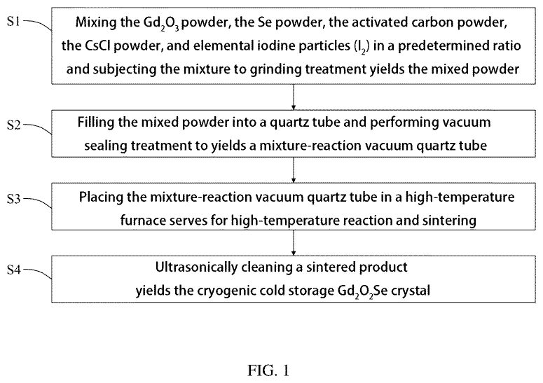

In some embodiments, referring to FIG. 1, the method for preparing the cold storage material includes the steps of:

S1: Mixing the Gd2O3 powder, the Se powder, the activated carbon powder, the CsCl powder, and the elemental iodine particles (I2) in the predetermined ratio and subjecting the mixture to the grinding treatment yields the mixed powder.

The molar ratio of the Gd2O3, the Se, and the activated carbon powder is 5:5:2.6 to 5:10:6, the mass ratio of the CsCl to the total mass of the Gd2O3, the Se, and the activated carbon powder is 3:2, and the mass ratio of the elemental iodine particles to the total mass of the Gd2O3, the Se, and the activated carbon powder is 1:20 to 10:20.

Additional amounts of the Gd2O3 powder, the Se powder, and the activated carbon powder influence phase composition of a product. The addition amounts below the aforementioned molar ratios make it difficult to synthesize the desired phase. Excessive Additional amounts, above the aforementioned molar ratio, result in formation of impurity phases. The CsCl powder functions as a flux agent influencing phase synthesis, while the I2 particles are used to control growth rate and generate required synthesis atmosphere, both affecting phase formation.

S2: Filling the mixed powder into a quartz tube and performing vacuum sealing treatment yields a mixture-reaction vacuum quartz tube.

The quartz tube has a thickness of at least 1 millimeter, an outer diameter of 20 millimeters, and a sealing height of 100-200 millimeters.

S3: Placing the mixture-reaction vacuum quartz tube in a high-temperature furnace serves for high-temperature reaction and sintering.

Sintering temperatures are programmed as follows: the initial temperature of 20-40° C., heating to 950-1100° C. over 600-800 minutes; maintaining at 950-1100° C. for 10-48 hours, then cooling to 500-750° C. over 3-5 days; and finally cooling from 500-750° C. to room temperature within 10-48 hours.

Dissolution and mixing of reactants are controlled by controlling heating duration and heating temperature. The heating duration and heating temperature below the aforementioned range result in insufficient dissolution and mixing of reactants, while excessive values introduce safety hazards. Crystal growth is controlled by regulating holding duration, cooling duration, and cooling temperature, where insufficient values fail to synthesize a product.

S4: Ultrasonically cleaning a sintered product yields the cryogenic cold storage Gd2O2Se crystal.

The ultrasonic cleaning duration is set to 24-72 hours, and an ultrasonic cleaning solution is ultrapure water.

The embodiments of the present application further provide an application of the cold storage material as described above in manufacture of cold storage devices or refrigeration equipment.

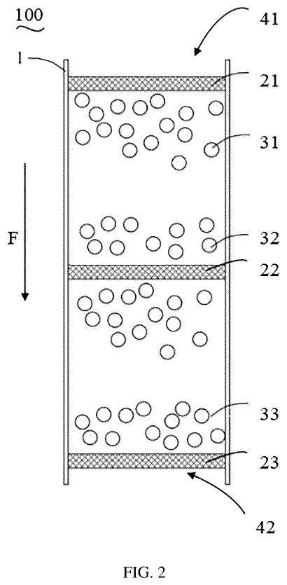

Referring to FIG. 2, an embodiment of the present application further provides a cold storage device 100, which includes a cold storage cylinder 1 and a first partition member 21, a second partition member 22, and a third partition member 23 arranged at intervals within the cold storage cylinder 1. The first partition member 21, the second partition member 22, and the third partition member 23 are configured to permit gas flow in a direction from the first partition member 21 toward the third partition member 23 (direction F). The first partition member 21 forms an air inlet 41, and the third partition member forms an air outlet 42. The first partition member 21, the second partition member 22, and the cold storage cylinder 1 form a first accommodation space. The second partition member 22, the third partition member 23 and the cold storage cylinder 1 form a second accommodation space. The first accommodation space is filled with a front-stage cold storage material 31 and a mid-stage cold storage material 32, and the second accommodation space is filled with a rear-stage cold storage material 33. In one embodiment, the front-stage cold storage material 31 and the mid-stage cold storage material 32 in the first accommodation space may be used in proportional mixtures, may be used solely, or may be placed without mixing.

In some embodiments, the front-stage cold storage material includes one or more of Er3Ni, Pb, Bi, HoCu2, and Ni; the mid-stage cold storage material includes the cold storage material as described above; the rear-stage cold storage material includes one or more of the cold storage materials as described above and Gd2O2S.

Furthermore, a phase transition temperature of the front-stage cold storage material, a phase transition temperature of the mid-stage cold storage material, and a phase transition temperature of the rear-stage cold storage material sequentially decrease.

A refrigerant gas enters the cold storage device 100 through the gas inlet 41, exchanges heat with the two-stage cold storage materials (the front-stage cold storage material 31, the mid-stage cold storage material 32, and the rear-stage cold storage material 33) inside the cold storage device 100, and exits through the gas outlet 42. The refrigerant gas transfers its heat to the two-stage cold storage materials, achieving additional cooling through different proportional combinations of the two-stage cold storage materials.

The following description further illustrates the present application through the embodiments.

### Embodiment 1

S1: Mixing the Gd2O3 powder, the Se powder, the activated carbon powder, the CsCl powder, and the elemental iodine particles (I2) in the predetermined ratio and subjecting the mixture to grinding treatment yielded the mixed powder. The molar ratio of the Gd2O3, the Se, and the activated carbon powder was 5:7:2.6, the mass ratio of the CsCl to the total mass of the Gd2O3, the Se, and the activated carbon powder was 3:2, and the mass ratio of the elemental iodine particles to the total mass of the Gd2O3, the Se, and the activated carbon powder was 3:20.

S2: Filling the mixed powder into the quartz tube and performing vacuum sealing treatment yielded the mixture-reaction vacuum quartz tube.

S3: Placing the mixture-reaction vacuum quartz tube in a high-temperature furnace served for high-temperature reaction and sintering. The sintering temperatures were programmed as follows: the initial temperature was 30° C., heated to 1050° C. over 600 minutes at a constant heating rate; maintained at the temperature for 24 hours, then cooled to 700° C. over 3 days; and finally cooled to room temperature within 24 hours.

S4: Ultrasonically cleaning the sintered product with ultrapure water ultrasonically for 24 hours yielded the Gd2O2Se crystal (cold storage material).

### Embodiment 2

S1: Mixing the Gd2O3, the Se powder, the activated carbon powder, the CsCl, and the elemental iodine particles (I2) in the predetermined ratio and subjecting the mixture to grinding treatment yielded the mixed powder. The molar ratio of the Gd2O3, the Se, and the activated carbon powder was 5:5:2.6, the mass ratio of the CsCl to the total mass of the Gd2O3, the Se, and the activated carbon powder was 3:2, and the mass ratio of the elemental iodine particles to the total mass of the Gd2O3, the Se, and the activated carbon powder was 1:20.

S2: Filling the mixed powder into the quartz tube and performing vacuum sealing treatment yielded the mixture-reaction vacuum quartz tube.

S3: Placing the mixture-reaction vacuum quartz tube in a high-temperature furnace served for high-temperature reaction and sintering. The sintering temperatures were programmed as follows: the initial temperature was 20° C., heated to 950° C. over 600 minutes at a constant heating rate; maintained the temperature for 48 hours, then cooled to 700° C. over 3 days; and finally cooled to room temperature within 10 hours.

S4: Ultrasonically cleaning the sintered product with ultrapure water ultrasonically for 24 hours yielded the Gd2O2Se crystal (cold storage material).

### Embodiment 3

S1: Mixing the Gd2O3, the Se powder, the activated carbon powder, the CsCl, and the elemental iodine particles (I2) in the predetermined ratio and subjecting the mixture to grinding treatment yielded the mixed powder. The molar ratio of the Gd2O3, the Se, and the activated carbon powder was 5:10:6, the mass ratio of the CsCl to the total mass of the Gd2O3, the Se, and the activated carbon powder was 3:2, and the mass ratio of the elemental iodine particles to the total mass of the Gd2O3, the Se, and the activated carbon powder was 10:20.

S2: Filling the mixed powder into the quartz tube and performing vacuum sealing treatment yielded the mixture-reaction vacuum quartz tube.

S3: Placing the mixture-reaction vacuum quartz tube in a high-temperature furnace served for high-temperature reaction and sintering. The sintering temperatures were programmed as follows: the initial temperature was 40° C., heated to 1100° C. over 800 minutes at a constant heating rate; maintained the temperature for 24 hours, then cooled to 500° C. over 5 days; and finally cooled to room temperature within 48 hours.

S4: Ultrasonically cleaning the sintered product with ultrapure water ultrasonically for 72 hours yielded the Gd2O2Se crystal (cold storage material).

### Test Example 1

An analysis experiment was conducted on composition and crystal structure of the Gd2O2Se crystal prepared in Embodiment 1.

(1) The prepared Gd2O2Se crystal was subjected to structural characterization.

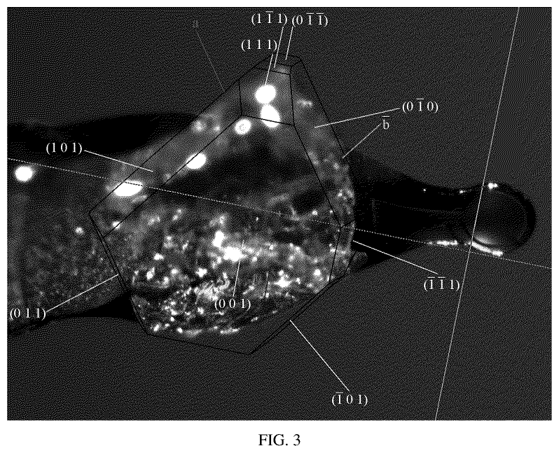

As shown in FIG. 3, under microscopic observation using a Bruker D8 VENTURE (type) single-crystal diffractometer as testing instrument, the crystal exhibits transparent hexagonal prism morphology with characteristic crystal plane structures.

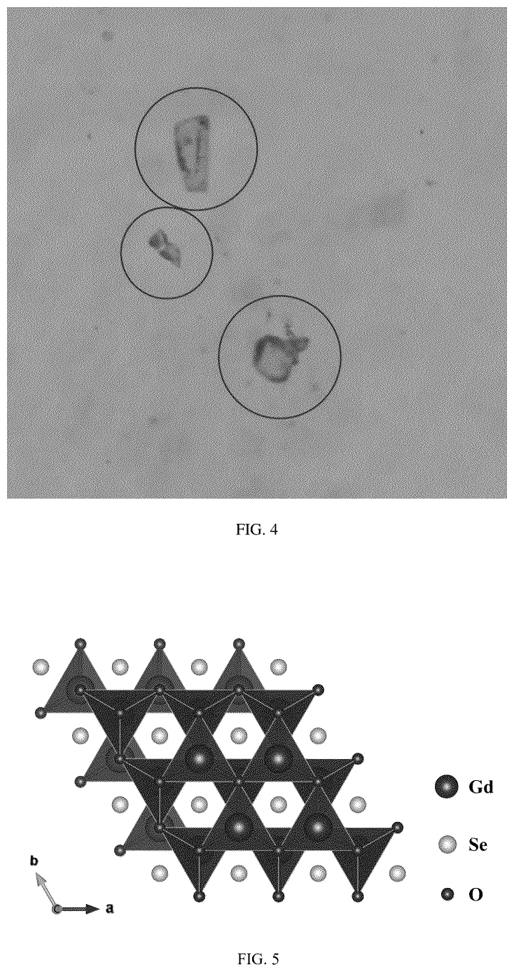

As shown in FIG. 4, the crystal exhibits transparent structural characteristics under optical microscope observation.

As shown in FIG. 5, structural testing of the Gd2O2Se crystal was performed under test conditions using the Bruker D8 VENTURE (type) single-crystal diffractometer with a Mo target and a Kα radiation source (wavelength=0.07107 nm) at a test temperature of 100 K, and structural analysis was conducted using Olex2 software, with the prepared Gd2O2Se crystal data provided in Table 1.

TABLE 1
Crystallographic data parameters of the Gd2O2Se crystal

| Molecular formula | Gd2O2Se |
|---|---|
| Molecular weight | 426.46 |
| Space group | P-3m1 |
| a-axis (Å) | 3.88510 |
| b-axis (Å) | 3.88510 |
| c-axis (Å) | 6.88 |
| □ = □ | 90 |
| γ | 120 |
| Volume V (Å3) | 89.933906 |
| Calculated density Dc (g · cm−3) | 7.856 |

(2) Compositional characterization was performed on the prepared Gd2O2Se crystal.

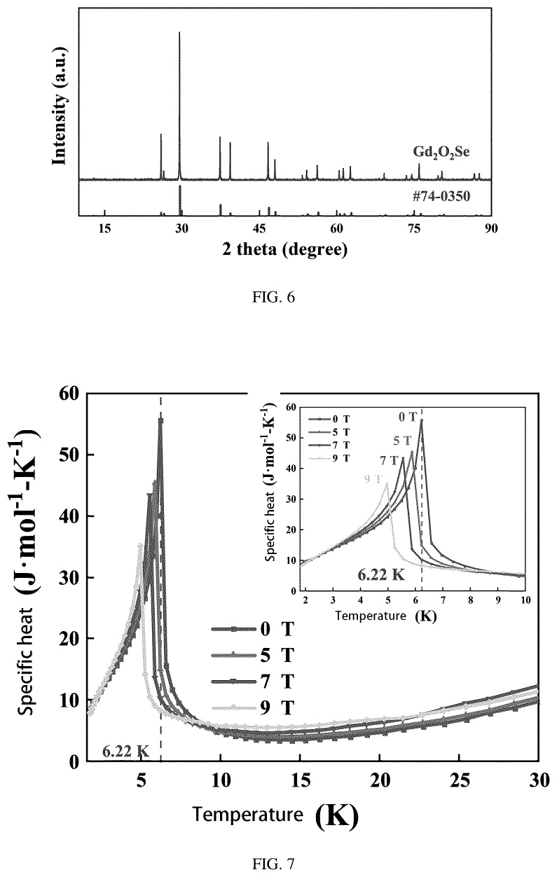

The prepared Gd2O2Se crystal powder was tested using a Rigaku SmartLab 9KW (type) powder X-ray diffractometer. The results shown in FIG. 6 demonstrate substantial agreement with the standard XRD pattern, confirming successful preparation of a target Gd2O2Se single-crystal powder.

### Test Example 2

Performance testing was conducted on the Gd2O2Se crystal prepared in Embodiment 1.

Specific heat data of the crystal sample prepared in Embodiment 1 were measured using a Physical Property Measurement System (PPMS). The single crystal sample prepared in Embodiment 1 was fixed on a specific heat platform with cryogenic adhesive for data testing. The temperature-dependent specific heat (Cp) curve was measured at a magnetic field of 0 T. To investigate the contribution of magnetic phase transitions to the specific heat in Gd2O2Se, the data in the 24-50 K range was fitted with a double-Debye model, and the fitted curve was extrapolated to 1.8 K to obtain the phonon-specific heat value. Subtracting the fitted phonon-specific heat data from the tested measured specific heat data yields the magnetic-specific heat value. FIG. 7 shows the specific heat versus temperature curve, revealing a distinct phase transition near 6.22 K and exhibiting high specific heat in the 1-10 K temperature range, with a peak specific heat value of 55.48 J/(mol3·K). Furthermore, the phase transition is progressively suppressed with increasing magnetic field strength, demonstrating high applicability for cold storage.

In summary, a cold storage material of the present application includes a Gd2O2Se crystal, which undergoes a phase transition near 6.22 K and exhibits high specific heat in a 1-10 K temperature range with pronounced magnetocaloric effects, making it suitable as a cold storage material at liquid helium temperatures. A preparation method of the cold storage material in the present application utilizes a flux growth technique for crystal growth, featuring simple operation, readily available raw materials, and high experimental safety. The prepared cold storage material exhibits advantages including stable physicochemical properties, excellent mechanical performance, low hygroscopicity, and ease of storage, facilitating subsequent processing and applications. A cold storage device of the present application enables more efficient refrigeration in a two-stage cold storage component by combining materials with different specific heat characteristics in a multi-stage arrangement within the regenerator. The front-stage cold storage material, mid-stage cold storage material, and rear-stage cold storage material have sequentially phase transition temperatures. When gas flows through the cold storage component, a multi-stage cooling process can occur, ultimately achieving more efficient refrigeration of the two-stage cold storage component.

It should be understood that the applications of the present invention are not limited to the examples described above, and those of ordinary skill in the art may make modifications or variations based on the above description, all of which should fall within the protection scope of the claims appended in the present application.

What is claimed is:

1. A cold storage material comprising: a Gd2O2Se crystal.

2. The cold storage material according to claim 1, wherein the Gd2O2Se crystal belongs to a trigonal crystal system, with a space group of P-3 m1.

3. The cold storage material according to claim 1, wherein the Gd2O2Se crystal has unit cell parameters of a=3.88510 Å, b=3.88510 Å, c=6.88 Å, □=90°, □=90°, γ=120°, and V=89.933906 Å3.

4. A method for preparing the cold storage material according to claim 1, comprising steps of; mixing Gd2O3, Se, activated carbon powder, CsCl, and elemental iodine particles in a predetermined ratio and subjecting a mixture to grinding treatment to obtain a mixed powder; and
sintering the mixed powder under vacuum conditions to obtain the cold storage material.

5. The method according to claim 4, wherein a molar ratio of the Gd2O3, the Se, and the activated carbon powder is 5:5:2.6 to 5:10:6;
a mass ratio of the CsCl to a total mass of the Gd2O3, the Se, and the activated carbon powder is 3:2 to 3:5; and
a mass ratio of the elemental iodine particles to the total mass of the Gd2O3, the Se, and the activated carbon powder is 1:20 to 10:20.

6. The method according to claim 4, wherein the sintering treatment comprises: heating from an initial temperature of 20-40° C. to 950-1100° C. at a constant heating rate over 600-800 minutes, maintaining temperature for 10-48 hours, after cooling to 500-750° C. over 3-5 days, then cooling to room temperature within 10-48 hours.

7. A cold storage device, comprising:
a cold storage cylinder,
a first partition member,
a second partition member, and
a third partition member arranged at intervals within the cold storage cylinder,
wherein the first partition member, the second partition member, and the third partition member are configured to permit gas flow in a direction from the first partition member toward the third partition member;
the first partition member, the second partition member, and the cold storage cylinder form a first accommodation space; and the second partition member, the third partition member, and the cold storage cylinder form a second accommodation space; and
the first accommodation space is filled with a front-stage cold storage material and a mid-stage cold storage material; and the second accommodation space is filled with a rear-stage cold storage material.

8. The cold storage device according to claim 7, wherein the front-stage cold storage material is selected from the group consisting of Er3Ni, Pb, Bi, HoCu2, and Ni;
the mid-stage cold storage material comprises a Gd2O2Se crystal; and
the rear-stage cold storage material is selected from the group consisting of the Gd2O2Se crystal and Gd2O2S.

9. The cold storage device according to claim 8, wherein a phase transition temperature of the front-stage cold storage material, a phase transition temperature of the mid-stage cold storage material, and a phase transition temperature of the rear-stage cold storage material sequentially decrease.
